(19) United States
(12) Patent Application Publication
(10) Pub. No.: US 2016/0373240 A1
(43) Pub. Date: Dec. 22, 2016

(54) Systems and Methods for Clock Recovery

(71) Applicant: Avago Technologies General IP (Singapore) Pte. Ltd., SINGAPORE (SG)

(72) Inventors: Mohammad Mobin, Orefield, PA (US); Bruce A. Wilson, San Jose, CA (US); Haitao Xia, San Jose, CA (US)

(21) Appl. No.: 14/740,371

(22) Filed: Jun. 16, 2015

(51) Int. Cl. H04L 7/00; H04B 1/16; H04B 1/00; H03L 7/08

(52) U.S. Cl. CPC H04L 7/0054; H03L 7/0807; H04B 1/16; H04B 1/0082

(57) ABSTRACT

Embodiments are related to systems and methods for data processing, and more particularly to systems and methods for clock recovery in a data receiver.

### FIELD OF THE INVENTION

Embodiments are related to systems and methods for data processing, and more particularly to systems and methods for clock recovery in a data receiver.

### BACKGROUND

A number of data transfer systems have been developed. Some transfer systems transfer clocked data without a clock. In such systems, the clock is recovered from the transferred data. In cases where transfer rates are high and/or noise is high, clock recovery may be inaccurate leading to set-up and hold violations and corresponding errors.

Hence, for at least the aforementioned reasons, there exists a need in the art for advanced systems and methods for enhancing sampling margins.

### SUMMARY

Embodiments are related to systems and methods for data processing, and more particularly to systems and methods for clock recovery in a data receiver.

Various embodiments of the present invention provide clock recovery systems. Such clock recovery systems include: a digital rotation detector circuit, a digital pulse width modulation circuit, a phase adjustment circuit, and a frequency adjustment circuit. The digital rotation detector circuit is operable to detect a rotation in a sample clock relative to a received data input to yield a detected rotation output. The digital pulse width modulation circuit is operable to generate a pulse width modulated digital output corresponding to the detected rotation output. The phase adjustment circuit is operable to provide a phase adjustment value based upon a phase error output. The frequency adjustment circuit is operable to generate a frequency correction adjustment value. based upon a combination of the phase error output and a rotation correction update input derived from the pulse width modulated digital output.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phrases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a serial data transfer system including a serial data receiver having enhanced clock recovery circuitry in accordance with various embodiments of the present inventions;

FIG. 2a shows an enhanced clock recovery circuit in accordance with various embodiments of the present invention;

FIG. 2b shows an example oscillator transfer function tradeoff scenario;

FIG. 2c shows an example of an uncorrected sampling and a corresponding corrected sampling;

FIG. 2d shows an example of rotation prepared samples;

FIGS. 3a-3d depict an implementation of a rotational frequency based pulse width modulation circuit in accordance with particular embodiments of the present invention;

FIGS. 4a-4d depict an implementation of another rotational frequency based pulse width modulation circuit in accordance with other embodiments of the present invention; and

FIGS. 5a-5d depict an implementation of yet another rotational frequency based pulse width modulation circuit in accordance with yet other embodiments of the present invention.

### DETAILED DESCRIPTION OF SOME EMBODIMENTS

Embodiments are related to systems and methods for data processing, and more particularly to systems and methods for clock recovery in a data receiver.

Various embodiments of the present invention provide systems, methods and/or devices for clock recovery provide an ability to meet storage SerDes requirements for (1) acquisition time, (2) handling of large clock parts per million (ppm), (3) acquisition and tracking of spread spectrum with large ppm spread with prescribed modulation frequency, and/or (4) meeting of jitter tolerance mask for serial attached storage (SAS) and personal component interconnect express (PCIe) standard.

Various embodiments of the present invention provide clock recovery systems. Such clock recovery systems include: a digital rotation detector circuit, a digital pulse width modulation circuit, a phase adjustment circuit, and a frequency adjustment circuit. The digital rotation detector circuit is operable to detect a rotation in a sample clock relative to a received data input to yield a detected rotation output. The digital pulse width modulation circuit is operable to generate a pulse width modulated digital output corresponding to the detected rotation output. The phase adjustment circuit is operable to provide a phase adjustment value based upon a phase error output. The frequency adjustment circuit is operable to generate a frequency correction adjustment value. based upon a combination of the phase error output and a rotation correction update input derived from the pulse width modulated digital output.

In some instances of the aforementioned embodiments, the system further includes an oscillator circuit operable to generate a recovered clock based upon a combination of the frequency correction adjustment value. and the phase adjustment value. In some such instances, the oscillator circuit is a voltage controlled oscillator, the frequency correction adjustment value. is a frequency adjustment voltage, and the phase adjustment value is a phase adjustment voltage.

In various instances of the aforementioned embodiments, the system further includes a phase detector circuit operable to detect a sampling phase error between a data input and a recovered clock, and to provide the phase error output corresponding to the sampling phase error. In some instances of the aforementioned embodiments, the digital rotation detector circuit receives a first instance of multiple samples of the received data input and a second instance of multiple samples of the received data input, and detects the rotation in the sample clock relative to the received data input based upon a comparison of the first instance and the second instance of the multiple samples. In some instances of the aforementioned embodiments, the systems further include: a low pass filter operable to filter to the detected rotation output to yield the rotation correction update input. In some such instances, a time constant of the low pass filter is programmable.

In one or more instances of the aforementioned embodiments, the frequency adjustment circuit includes an integrator circuit operable to integrate a sum of a value derived from the phase error output and the rotation correction update input to yield the frequency correction adjustment value. In various instances of the aforementioned embodiments, the rotation correction update input is the same as the detected rotation output. In other instances, the systems further include a digital to analog converter circuit operable to convert the detected rotation output from a digital domain to yield the rotation correction update input in an analog domain. In some cases, the system is implemented as part of a storage device. In various cases, the system is implemented as part of an integrated circuit.

Other embodiments provide methods for clock recovery. Such methods include: receiving a data input; sampling the data input using a sampling circuit to yield at least three samples; detecting a frequency rotation based at least in part on the three samples to yield a detected rotation output; detecting a phase error based at least in part on the three samples to yield a phase error output; generating a pulse width modulated digital output corresponding to the detected rotation output; generating a phase adjustment value based at least in part on the phase error output; and generating a frequency correction adjustment value. based upon a combination of the phase error output and a rotation correction update input derived from the pulse width modulated digital output.

In some instances of the aforementioned embodiments, the methods further include using a voltage controlled oscillator to generate a recovered clock based upon a combination of the frequency correction adjustment value. and the phase adjustment value. In such instances, the frequency correction adjustment value. is a frequency adjustment voltage, and wherein the phase adjustment value is a phase adjustment voltage. In one or more instances of the aforementioned embodiments, the phase error output corresponds to a sampling phase error of a sampling clock relative to the data input. In various instances of the aforementioned embodiments, the methods further include filtering the detected rotation output using a low pass filter to yield the rotation correction update input. In some cases, the methods further include programming a time constant of the low pass filter.

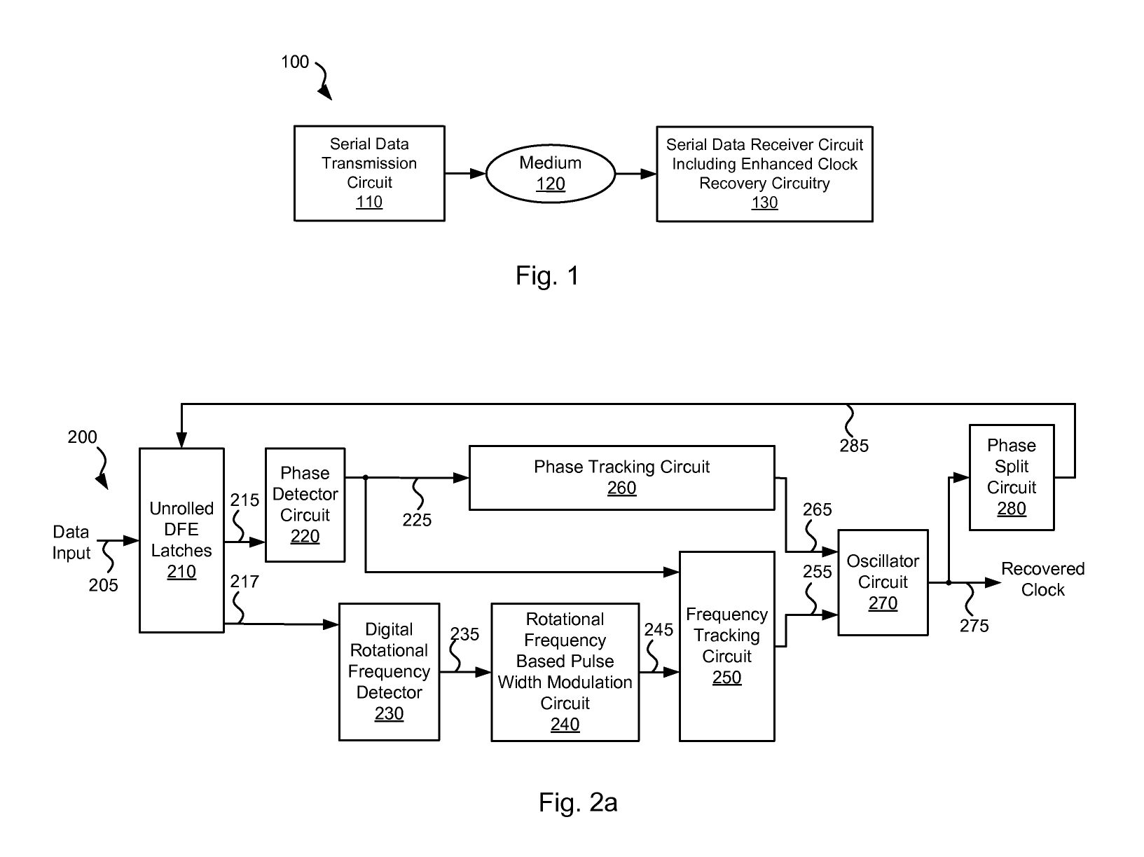

Turning to FIG. 1, a serial data transfer system 100 is shown that includes a serial data transmission circuit 110 and a serial data receiver circuit 130. Serial data transmission circuit 110 may be any circuit known in the art for generating a stream a serial data to be transferred to serial data receiver circuit 130 via a medium 120. Based upon the disclosure provided herein, one of ordinary skill in the art will recognize a variety of data transmission circuitry that may be used in relation to different embodiments of the present invention. Medium 120 may be, but is not limited to, a wired or wireless transfer medium. Such wired transfer mediums may be a metal wire transfer medium capable of transmitting electrical signal, or may be an optical transfer medium capable of transferring light. Based upon the disclosure provided herein, one of ordinary skill in the art will recognize a variety of wired transfer media that may be used in relation to different embodiments of the present invention. The aforementioned wireless transfer mediums may be an atmosphere capable of transmitting, for example, radio frequency signals. Based upon the disclosure provided herein, one of ordinary skill in the art will recognize a variety of wireless transfer media that may be used in relation to different embodiments of the present invention.

Serial data receiver circuit 130 receives the serial data via medium 120. The received serial data is sampled and the sampled data is provided to one or more circuits (not shown) for processing. As part of receiving the serial data, enhanced clock recovery circuitry included in serial data receiver circuit 130 recovers a clock from the received data. In operation, a rotational frequency detector over-samples an input serial bit stream, and detects which direction the sampling clock walks upon detection a cycle slip. Once the direction of the cycle slip is detected, the clock frequency is incremented or decremented to chase the data in the same direction by injecting a ppm in a second order loop filter path of a clock data recovery circuit. This results in a slow down of the cycle slip rate. If cycle slip still happens, an additional part per million is injected in the second order loop filter path until the clock data recovery is brought into range of other circuitry of the clock data recovery circuitry. At this point the clock data recovery circuitry starts to track the data.

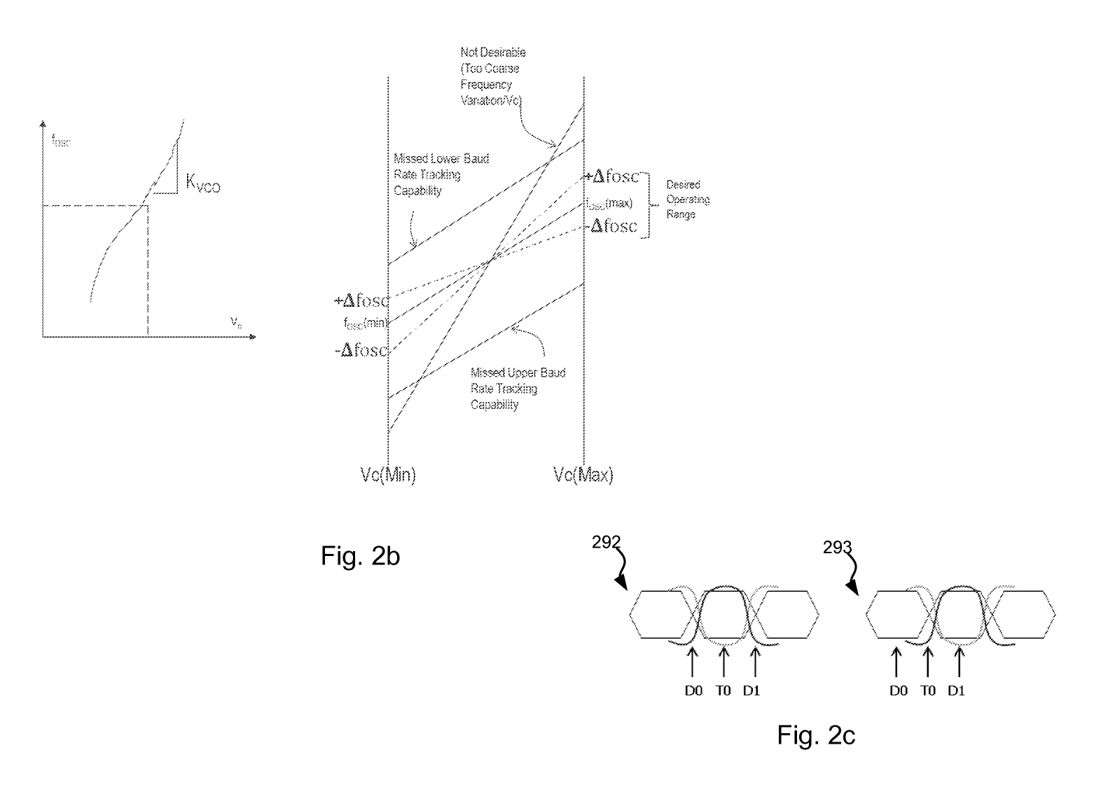

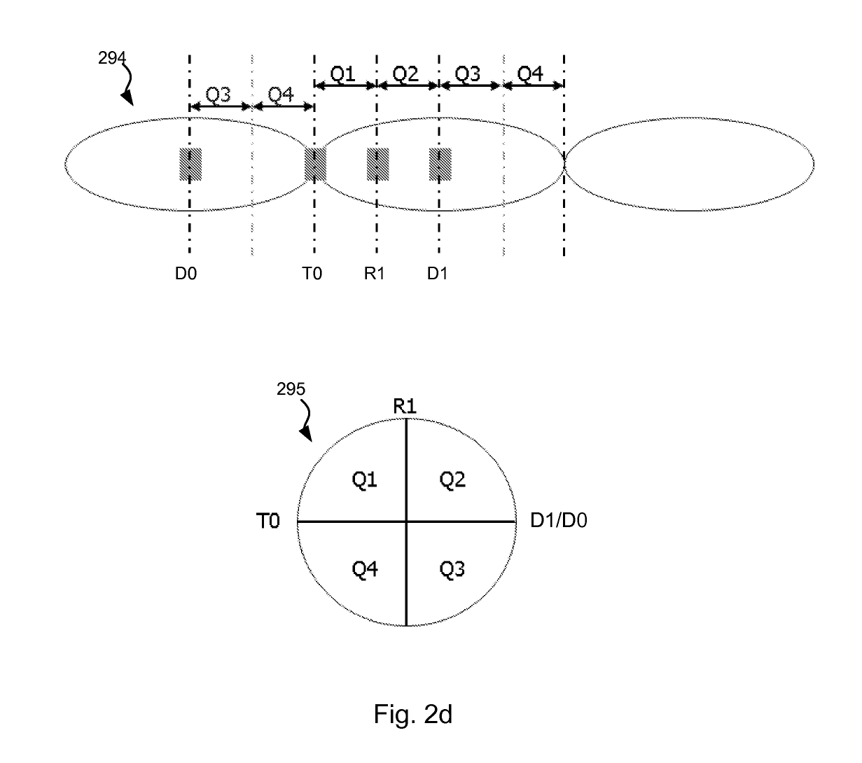

Turning to FIG. 2a, an enhanced clock recovery circuit 200 is shown in accordance with various embodiments. Clock data recovery circuit 200 includes unrolled decision feedback equalizer circuits (unrolled DFE latches 210) that oversample a data input 205 to yield transition and data samples 215. Turning to FIG. 2c, graphically depicts an example of transition and data samples 215 in relation to an uncorrected sampling 292 and a corresponding corrected sampling 293. As shown, transition and data samples 215 includes two data samples D0, D1 that when corrected should be sampled near the middle of two consecutive eyes, and a transition sample T0 that when corrected should be sampled near the transition of two consecutive eyes. As shown, uncorrected sampling 292 shows the data samples D0, D1 being sampled away from the center of respective eyes and transition sample T0 being sampled away from the transition between respective eyes. As I (inphase) and Q (quadrature) clocks 285 are fed back from a phase split circuit 280 are adjusted corrected sampling 293 occurs where the data samples D0, D1 are being sampled near the center of respective eyes and transition sample T0 being near the transition between respective eyes. Unrolled DFE latches 210 may be any circuit known in the art that generates transition and data samples 215.

Additionally, unrolled DFE latches 210 provides rotation prepared samples 217 to a digital rotational frequency detector 230. Rotation prepared samples 217 correspond to different sampling points across multiple units of data input 205. Turning to FIG. 2d, a graphic 294 shows multiple eyes of data input 205 where data D0, D1 is sampled, a transition T0 is sampled, and a roaming latch R0 samples. D0, D1, T0, R1 correspond to rotation prepared samples 217. In this example rotation is detected on a quadrant to quadrant basis where the quadrants are labeled Q1, Q2, Q3, Q4 as shown in graphic 295. Where rotation prepared samples 217 is defined by the array {D0, T0, R1, D1} of FIG. 2d, the following table shows the correspondence between rotation prepared samples 217 and graphic 295.

| Rotation prepared samples 217 | |
|---|---|
| {D0, T0, R1, D1} | Quadrant of Graphic 295 |
| 1000 | Q3/Q4 |
| 0111 | Q3/Q4 |
| 1100 | Q1 |
| 0011 | Q1 |
| 1110 | Q2 |
| 0001 | Q2 |

A phase detector circuit 220 applies a phase detection to transition and data samples 215 to generate an expected sampling phase for a recovered clock 275. Phase detector circuit 220 may be any circuit known in the art that detects a misalignment of a sampling phase. Based upon the disclosure provided herein, one of ordinary skill in the art will recognize a variety of phase detector circuits that may be used in relation to different embodiments of the present invention. Phase detector circuit 220 asserts a phase error output 225 as: (1) a ‘+1’ when the phase of recovered clock 275 is to be moved forward (i.e., increase in frequency), (2) a ‘−1’ when the phase of recovered clock 275 is to be moved backward (i.e., decrease in frequency), or (3) a ‘0’ when the phase of recovered clock 275 is correct (i.e., no data transition is detected). A phase tracking circuit 260 operates to generate an analog phase input voltage 265 corresponding to phase error output 225. Phase tracking circuit 260 may be any circuit known in the art for generating an oscillator input based upon a phase error signal. Based upon the disclosure provided herein, one of ordinary skill in the art will recognize a variety of circuits that may be used to implement phase tracking circuit 260. A frequency tracking circuit 250 operates to generate an interim frequency output (not shown) corresponding to phase error output 225. Generation of the interim frequency output corresponding to phase error output 225 may be done using any frequency tracking circuit known in the art. In one particular embodiment, phase error output 225 is provided to a charge pump (not shown) included as part of frequency tracking circuit 250, and the charge pump yields an analog signal corresponding to phase error output 225 as is known in the art. Based upon the disclosure provided herein, one of ordinary skill in the art will recognize a variety of circuits that may be used to generate the aforementioned interim frequency output of frequency tracking circuit 250.

A digital rotational frequency detector circuit 230 detects a rotation of the sampling based upon successive instances of rotation prepared samples 217. In particular, digital rotational frequency detector circuit 230 detects: (1) a shift of the received data from one cycle of a recovered clock to a next cycle of the clock; (2) continuation of the received data within one cycle of the recovered clock; or (3) a shift of the received data from one cycle of a recovered clock to a previous cycle of the clock. Where a shift to the next cycle is detected, digital rotational frequency detector circuit 230 asserts a rotation output 235 as a “+1”. Alternatively, where a shift to the previous cycle is detected, digital rotational frequency detector circuit 230 asserts rotation output 235 as a “−1”. As yet another alternative where no shift is indicated, digital rotational frequency detector circuit 230 asserts rotation output 235 as a “0”. Any circuit known in the art for detecting forward cycle shift and reverse cycle shift may be used in place of digital rotational frequency detector circuit 230.

Rotation output 235 is provided to a rotational frequency based pulse width modulation circuit 240. Rotational frequency based pulse width modulation circuit 240 provides a pulse width modulated output 245 where the pulse width modulates at a logic ‘1’ for an increased number of clock cycles when rotation output 235 as a “−1”. Modulating at a logic ‘1’ for an increased number of clock cycles results modulated output 245 with a net positive additive value. In contrast, rotational frequency based pulse width modulation circuit 240 modulates modulated output 245 at a logic ‘0’ for an increased number of clock cycles when rotation output 235 as a “+1”. Modulating at a logic ‘0’ for an increased number of clock cycles results in modulated output 245 with a net negative additive value. Where rotation output 235 as a “0”, rotational frequency based pulse width modulation circuit 240 provides modulated output 245 that has close to a net zero additive value. In some embodiments, rotational frequency based pulse width modulation circuit 240 is implemented using a counter where incrementing the counter when the least significant bit of the counter is a logic ‘1’ is disabled for one or more clock cycles when rotation output 235 as a “−1”, and incrementing the counter when the least significant bit of the counter is a logic ‘0’ is disabled for one or more clock cycles when rotation output 235 as a “+1”. The least significant bit of the counter, either raw or further processed, is provided as modulated output 245. As such, modulated output 245 exhibits: (1) a fifty percent duty cycle when rotation output 235 as a “0”, (2) an extended a logic ‘1’ for one or more clock cycles when rotation output 235 as a “−1”, or (2) an extended a logic ‘0’ for one or more clock cycles when rotation output 235 as a “+1”.

Enhancing clock recovery by adding an enhancement path consisting of digital rotational frequency detector circuit 230 and rotational frequency based pulse width modulation circuit 240 increases flexibility to control clock recovery. In operation, rotational frequency detector circuit 230 starts from a default non-zero value to aid in increasing CDR capture range. At a programmed delay the gain drops and eventually reaches a final value (e.g., zero) which ends the contribution of the enhancement path to the clock recovery. In some cases, the final gain used in the rotational frequency detector circuit 230 is non-zero which in particular situations reduces the possibility of the clock recovery from going out of lock due to a glitch or other unexpected event.

Frequency tracking circuit 250 additionally includes an analog summation circuit (not shown) that operates to add the aforementioned interim frequency output to modulated output 245 to yield an analog frequency correction input 255. In one embodiment, the analog summation circuit is an analog integrator circuit. Based upon the disclosure provided herein one of ordinary skill in the art will recognize a variety of analog summation circuits that may be used in relation to different embodiments. An analog phase input voltage 265 and an analog frequency correction input voltage 255 are provided to an oscillator circuit 270 where they are used to modify the phase/frequency of recovered clock 275. In some cases, oscillator circuit 270 is an LC oscillator circuit. In such cases, the combination of analog phase input voltage 265 and analog frequency correction input voltage 255 are used to modify the control voltage of the LC oscillator circuit. Recovered clock 275 is provided to a phase split circuit 280 that splits recovered clock 275 into I and Q clocks 285 used for oversampling a symbol at DFE latches 210.

In some cases, adding the aforementioned enhancement path avoids the need for additional pipeline stages to perform clock recovery. Such added pipeline stages often introduce excessive loop latency that makes clock data recovery less responsive to fast varying jitter. This in turn reduces clock data recovery bandwidth and hence affects the clock data recovery jitter tolerance capabilities. In order to overcome the above mentioned limitation of traditional digital clock data recovery circuits, the aforementioned enhancement path uses analog circuitry to enhance clock data recovery.

In various embodiments, the voltage to frequency curve (i.e., the slope of the oscillator transfer function) is adjusted by adding an input from the aforementioned enhancement path is sufficiently steep to allow for a large part per million range while not too steep which would result in excessive jitter in combination with proper loop filter bandwidth. The oscillator transfer function allows frequency tracking from the lowest baud rate to highest baud rate. The slope is not too steep as to create frequency overshoot and not too shallow that it cannot track across supported baud rate. One example, of a tradeoff in oscillator control is shown in FIG. 2b.

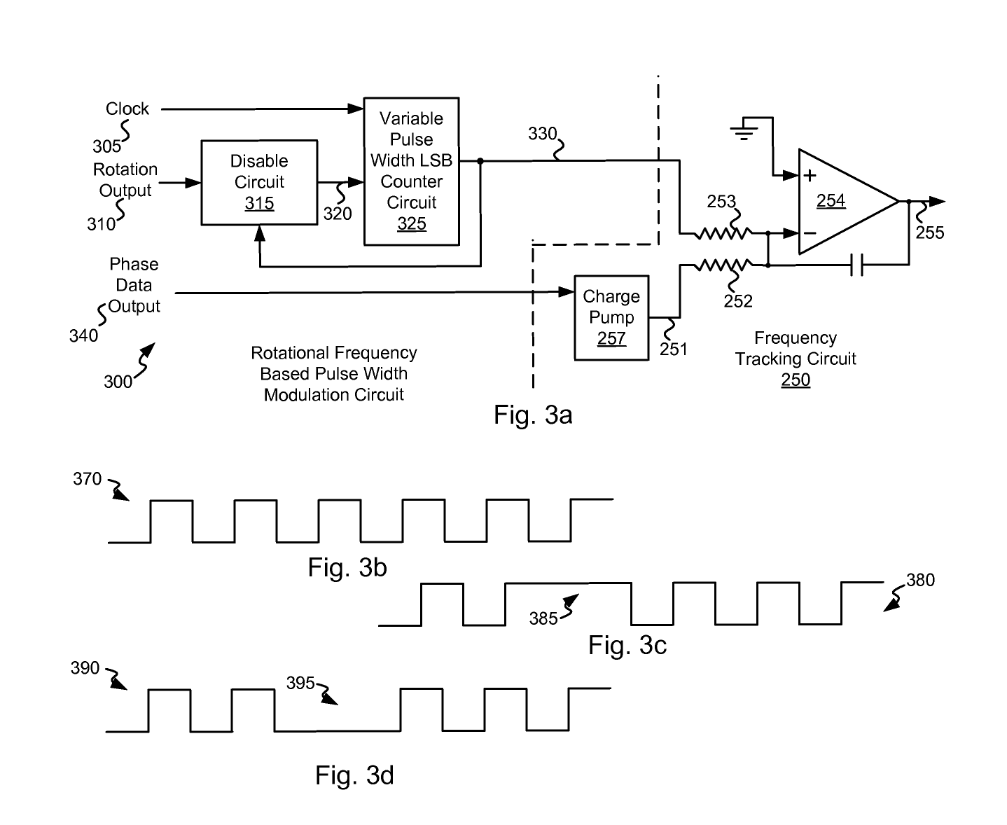

Turning to FIG. 3a, an implementation of a rotational frequency based pulse width modulation circuit 300 is shown in accordance with particular embodiments of the present invention. Rotational frequency based pulse width modulation circuit 300 may be used in place of rotational frequency based pulse width modulation circuit 240 discussed above in relation to FIG. 2. Where rotational frequency based pulse width modulation circuit 300 is used in place of rotational frequency based pulse width modulation circuit 240, a rotation output 310 is connected to rotation output 235 of FIG. 2, and a phase data output 340 is connected to phase error output 225 of FIG. 2.

As shown, rotational frequency based pulse width modulation circuit 300 includes a variable pulse width least significant bit counter circuit 325 where the counter is incremented synchronous to a clock 305 based upon an enable signal 320. Enable signal 320 enables variable pulse width least significant bit counter circuit 325 to increment on all rising edges of clock 305 when rotation output 310 is a zero indicating no phase slip. Such an assertion of enable 320 results in a pulse output 330 with a fifty percent duty cycle pattern 370 as shown in FIG. 3b.

Alternatively, where rotation output 310 is a negative one indicating a slip to the preceding cycle, disable circuit 315 de-asserts enable 320 when pulse 330 is a logic ‘1’ for one or more clock cycles such that the ‘1’ at pulse 330 is extended beyond the default fifty percent duty cycle. Such an assertion of enable 320 results in a pulse output 330 with a modified duty cycle pattern 380 as shown in FIG. 3c where one or more cycles of a logic ‘1’ (e.g., a cycle 385) are extended. As yet another alternative, where rotation output 310 is a positive one indicating a slip to the next cycle, disable circuit 315 de-asserts enable 320 when pulse 330 is a logic ‘0’ for one or more clock cycles such that the ‘0’ at pulse 330 is extended beyond the default fifty percent duty cycle. Such an assertion of enable 320 results in a pulse output 330 with a modified duty cycle pattern 390 as shown in FIG. 3d where one or more cycles of a logic ‘0’ (e.g., a cycle 395) are extended. Of note, pulse output 330 is a digital pulse.

As discussed above in relation to FIG. 2, frequency tracking circuit 250 includes a charge pump 257 that generates an analog signal 251 corresponding to phase error output 225 as is known in the art. Analog signal 251 is passed through a resistor 252 to a negative feedback connected operational amplifier 254. Pulse output 330 is passed through a resistor 253 to negative feedback connected operational amplifier 254. The sum of pulse output 330 and analog signal 251 is integrated by negative feedback connected operational amplifier 254 to yield analog frequency input voltage 255.

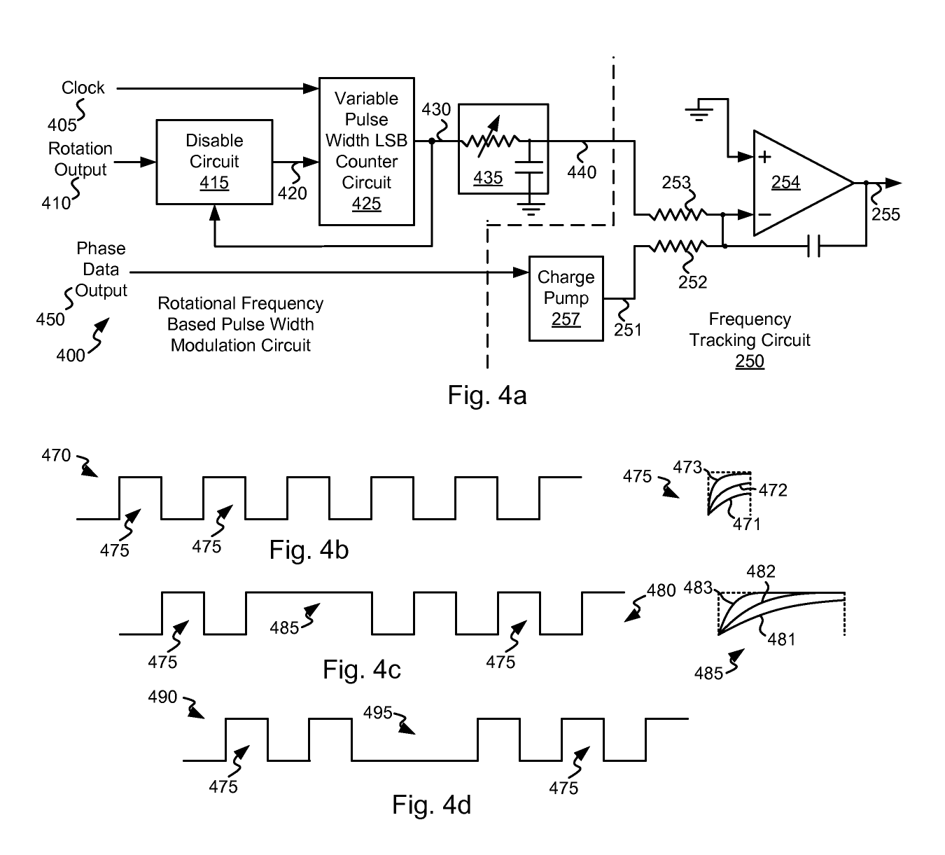

Turning to FIG. 4a, another implementation of a rotational frequency based pulse width modulation circuit 400 is shown in accordance with particular embodiments of the present invention. Rotational frequency based pulse width modulation circuit 400 may be used in place of rotational frequency based pulse width modulation circuit 240 discussed above in relation to FIG. 2. Where rotational frequency based pulse width modulation circuit 400 is used in place of rotational frequency based pulse width modulation circuit 240, a rotation output 410 is connected to rotation output 235 of FIG. 2, and a phase data output 450 is connected to phase error output 225 of FIG. 2.

As shown, rotational frequency based pulse width modulation circuit 400 includes a variable pulse width least significant bit counter circuit 425 where the counter is incremented synchronous to a clock 405 based upon an enable signal 420. Enable signal 420 enables variable pulse width least significant bit counter circuit 425 to increment on all rising edges of clock 405 when rotation output 410 is a zero indicating no phase slip. Such an assertion of enable 420 results in a pulse output 430 with a fifty percent duty cycle pattern 470 as shown in FIG. 4b.

Alternatively, where rotation output 410 is a negative one indicating a slip to the preceding cycle, disable circuit 415 de-asserts enable 420 when pulse 430 is a logic ‘1’ for one or more clock cycles such that the ‘1’ at pulse 430 is extended beyond the default fifty percent duty cycle. Such an assertion of enable 420 results in a pulse output 430 with a modified duty cycle pattern 480 as shown in FIG. 4c where one or more cycles of a logic ‘1’ (e.g., a cycle 485) are extended. As yet another alternative, where rotation output 410 is a positive one indicating a slip to the next cycle, disable circuit 415 de-asserts enable 420 when pulse 430 is a logic ‘0’ for one or more clock cycles such that the ‘0’ at pulse output 430 is extended beyond the default fifty percent duty cycle. Such an assertion of enable 420 results in a pulse output 430 with a modified duty cycle pattern 490 as shown in FIG. 4d where one or more cycles of a logic ‘0’ (e.g., a cycle 495) are extended. Of note, pulse output 430 is a digital pulse.

Pulse output 430 is provided to a tunable low pass filter 435 including a variable resistor and a capacitor. By adjusting the variable resistor of tunable low pass filter 435, the rise time of pulse output 430 may be adjusted. Using fifty percent duty cycle pattern 470 of FIG. 4b, each pulse 475 of fifty percent duty cycle pattern 470 exhibits a rise time (e.g., a signal 471, a signal 472, or a signal 473) exhibits a rise time corresponding to the tunable low pass filter 435. Where the pulse is extended, such as with pulse 485, the effect of tunable low pass filter 435 exhibits a change in the rise time (e.g., a signal 481, a signal 482, or a signal 483). Each of the pulses exhibits this modified rise time to yield a fraction of the full scale voltage swing of pulse output 430 (i.e., an adjusted output 440).

As discussed above in relation to FIG. 2, frequency tracking circuit 250 includes a charge pump 257 that generates an analog signal 251 corresponding to phase error output 225 as is known in the art. Analog signal 251 is passed through a resistor 252 to a negative feedback connected operational amplifier 254. Smoothed output 440 is passed through a resistor 253 to negative feedback connected operational amplifier 254. The sum of pulse output 430 and analog signal 251 is integrated by negative feedback connected operational amplifier 254 to yield analog frequency input voltage 255.

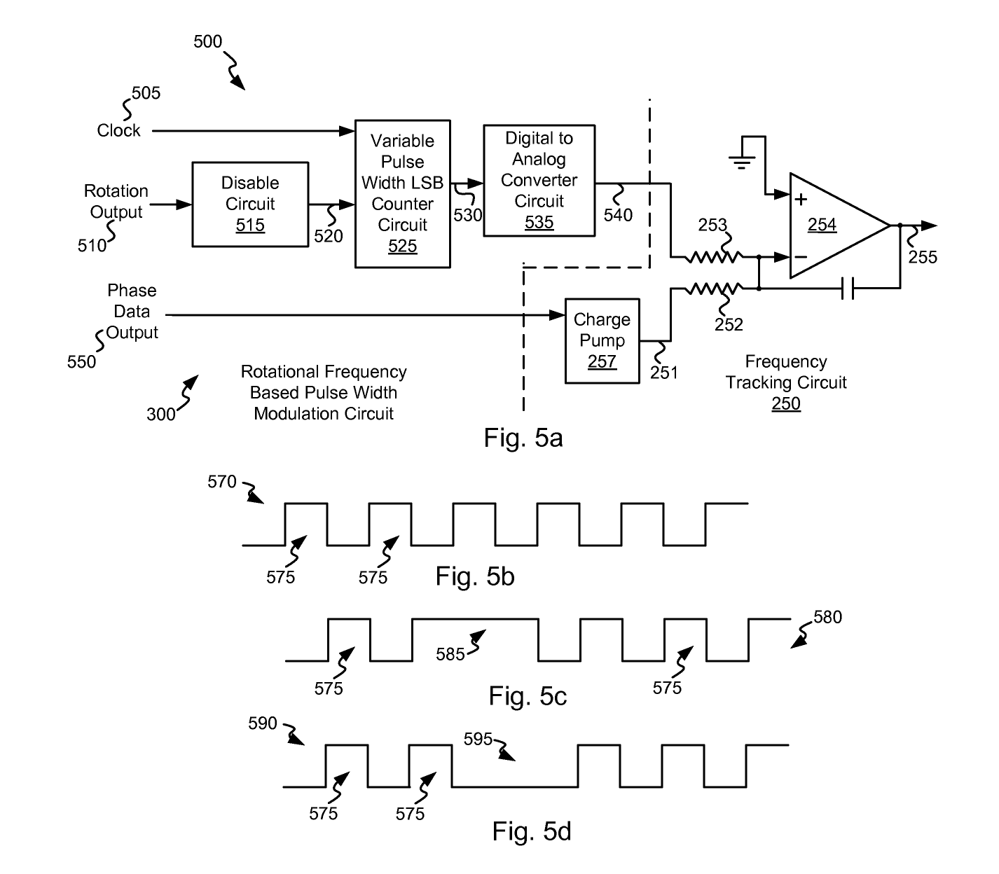

Turning to FIG. 5a, yet another implementation of a rotational frequency based pulse width modulation circuit 500 is shown in accordance with particular embodiments of the present invention. Rotational frequency based pulse width modulation circuit 400 may be used in place of rotational frequency based pulse width modulation circuit 240 discussed above in relation to FIG. 2. Where rotational frequency based pulse width modulation circuit 500 is used in place of rotational frequency based pulse width modulation circuit 240, a rotation output 510 is connected to rotation output 235 of FIG. 2, and a phase data output 550 is connected to phase error output 225 of FIG. 2.

As shown, rotational frequency based pulse width modulation circuit 500 includes a variable pulse width least significant bit counter circuit 525 where the counter is incremented synchronous to a clock 505 based upon an enable signal 520. Enable signal 520 enables variable pulse width least significant bit counter circuit 525 to increment on all rising edges of clock 505 when rotation output 510 is a zero indicating no phase slip. Such an assertion of enable 520 results in a pulse output 530 with a fifty percent duty cycle pattern 570 as shown in FIG. 5b.

Alternatively, where rotation output 510 is a negative one indicating a slip to the preceding cycle, disable circuit 515 de-asserts enable 520 when pulse 530 is a logic ‘1’ for one or more clock cycles such that the ‘1’ at pulse 530 is extended beyond the default fifty percent duty cycle. Such an assertion of enable 520 results in a pulse output 530 with a modified duty cycle pattern 580 as shown in FIG. 5c where one or more cycles of a logic ‘1’ (e.g., a cycle 585) are extended. As yet another alternative, where rotation output 510 is a positive one indicating a slip to the next cycle, disable circuit 515 de-asserts enable 520 when pulse output 530 is a logic ‘0’ for one or more clock cycles such that the ‘0’ at pulse output 530 is extended beyond the default fifty percent duty cycle. Such an assertion of enable 520 results in a pulse output 530 with a modified duty cycle pattern 590 as shown in FIG. 5d where one or more cycles of a logic ‘0’ (e.g., a cycle 595) are extended. Of note, pulse output 530 is a digital pulse.

Pulse output 530 is provided to a digital to analog converter circuit 535 that converts the pulses into a series of analog signals 540. As discussed above in relation to FIG. 2, frequency tracking circuit 250 includes a charge pump 257 that generates an analog signal 251 corresponding to phase error output 225 as is known in the art. Analog signal 251 is passed through a resistor 252 to a negative feedback connected operational amplifier 254. The series of analog signals 540 is passed through a resistor 253 to negative feedback connected operational amplifier 254. The sum of the series of analog signals 540 and analog signal 251 is integrated by negative feedback connected operational amplifier 254 to yield analog frequency correction input 255.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent, albeit such a system would not be a circuit. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A clock recovery system, the system comprising:
a digital rotation detector circuit operable to detect a rotation in a sample clock relative to a received data input to yield a detected rotation output;
a digital pulse width modulation circuit operable to generate a pulse width modulated digital output corresponding to the detected rotation output;
a phase adjustment circuit operable to provide a phase adjustment value based upon a phase error output; and
a frequency adjustment circuit operable to generate a frequency correction adjustment value. based upon a combination of the phase error output and a rotation correction update input derived from the pulse width modulated digital output.

2. The system of claim 1, wherein the system further comprises:
an oscillator circuit operable to generate a recovered clock based upon a combination of the frequency correction adjustment value. and the phase adjustment value.

3. The system of claim 2, wherein the oscillator circuit is a voltage controlled oscillator, wherein the frequency correction adjustment value. is a frequency adjustment voltage, and wherein the phase adjustment value is a phase adjustment voltage.

4. The system of claim 1, wherein the system further comprises:
a phase detector circuit operable to detect a sampling phase error between a data input and a recovered clock, and to provide the phase error output corresponding to the sampling phase error.

5. The system of claim 1, wherein the digital rotation detector circuit receives a first instance of multiple samples of the received data input and a second instance of multiple samples of the received data input, and detects the rotation in the sample clock relative to the received data input based upon a comparison of the first instance and the second instance of the multiple samples.

6. The system of claim 1, wherein the system further comprises:
a low pass filter operable to filter to the detected rotation output to yield the rotation correction update input.

7. The system of claim 6, wherein a time constant of the low pass filter is programmable.

8. The system of claim 1, wherein the frequency adjustment circuit includes an integrator circuit operable to integrate a sum of a value derived from the phase error output and the rotation correction update input to yield the frequency correction adjustment value.

9. The system of claim 1, wherein the rotation correction update input is the same as the detected rotation output.

10. The system of claim 1, wherein the system further comprises:
a digital to analog converter circuit operable to convert the detected rotation output from a digital domain to yield the rotation correction update input in an analog domain.

11. The system of claim 1, wherein the system is implemented as part of a storage device.

12. The system of claim 1, wherein the system is implemented as part of an integrated circuit.

13. A method for clock recovery, the method comprising:
receiving a data input;
sampling the data input using a sampling circuit to yield at least three samples;
detecting a frequency rotation based at least in part on the three samples to yield a detected rotation output;
detecting a phase error based at least in part on the three samples to yield a phase error output;
generating a pulse width modulated digital output corresponding to the detected rotation output;
generating a phase adjustment value based at least in part on the phase error output; and
generating a frequency correction adjustment value. based upon a combination of the phase error output and a rotation correction update input derived from the pulse width modulated digital output.

14. The method of claim 13, the method further comprising:
using a voltage controlled oscillator to generate a recovered clock based upon a combination of the frequency correction adjustment value. and the phase adjustment value, wherein the frequency correction adjustment value. is a frequency adjustment voltage, and wherein the phase adjustment value is a phase adjustment voltage.

15. The method of claim 13, wherein the phase error output corresponds to a sampling phase error of a sampling clock relative to the data input.

16. The method of claim 13, the method further comprising:
filtering the detected rotation output using a low pass filter to yield the rotation correction update input.

17. The method of claim 16, the method further comprising:
programming a time constant of the low pass filter.

18. The method of claim 13, wherein generating the frequency correction adjustment value. comprises:
summing a value derived from the phase error output and the rotation correction update input to yield a sum value; and
integrating the sum value to yield the frequency correction adjustment value.

19. The method of claim 13, the method further comprising:
converting the detected rotation output from a digital domain to yield the rotation correction update input in an analog domain.

20. A device, the device comprising:
a serial data receiver, the serial data receiver including:
a digital rotation detector circuit operable to detect a rotation in a sample clock relative to a received data input to yield a detected rotation output;
a digital pulse width modulation circuit operable to generate a pulse width modulated digital output corresponding to the detected rotation output;
a phase adjustment circuit operable to provide a phase adjustment value based upon a phase error output; and
a frequency adjustment circuit operable to generate a frequency correction adjustment value. based upon a combination of the phase error output and a rotation correction update input derived from the pulse width modulated digital output.
